(19) United States
(12) Patent Application Publication
(10) Pub. No.: US 2025/0081752 A1
(43) Pub. Date: Mar. 6, 2025

(54) DISPLAY DEVICE

(71) Applicant: Japan Display Inc., Tokyo (JP)

(72) Inventors: Hideyuki TAKAHASHI, TOKYO (JP); Hiroyuki KIMURA, TOKYO (JP)

(73) Assignee: Japan Display Inc., Tokyo (JP)

(21) Appl. No.: 18/823,698

(22) Filed: Sep. 4, 2024

(30) Foreign Application Priority Data
Sep. 6, 2023 (JP) 2023-144495

(51) Int. Cl. H10K 59/122; H10K 59/131; H10K 59/40

(52) U.S. Cl. CPC H10K 59/122; H10K 59/131; H10K 59/40

(57) ABSTRACT

According to one embodiment, a display device includes display elements each including a lower electrode, an upper electrode and an organic layer between the lower electrode and the upper electrode, a rib which has a plurality of pixel apertures overlapping the display elements, respectively, and a partition which includes a conductive lower portion provided on the rib and an upper portion protruding from a side surface of the lower portion and surrounds each of the display elements. Further, the partition is divided into a plurality of segments for detecting an object which is in contact with or close to a display area including the display elements.

### CROSS-REFERENCE TO RELATED APPLICATIONS

This application is based upon and claims the benefit of priority from Japanese Patent Application No. 2023-144495, filed Sep. 6, 2023, the entire contents of which are incorporated herein by reference.

### FIELD

Embodiments described herein relate generally to a display device.

### BACKGROUND

Recently, display devices to which an organic light emitting diode (OLED) is applied as a display element and which comprise the function of a touch sensor detecting the operation of the user for a display area have been put into practical use. In this type of display devices, the reduction in the manufacturing cost and the improvement of the display quality are required.

### BRIEF DESCRIPTION OF THE DRAWINGS

FIG. 1 is a diagram showing a configuration example of a display device according to a first embodiment.

FIG. 2 is a schematic plan view showing an example of the layout of subpixels.

FIG. 3 is a schematic cross-sectional view of the display device along the III-III line of FIG. 2.

FIG. 4 is a schematic plan view showing elements for detecting touch operation for a display area.

FIG. 5 is a schematic enlarged plan view of the segments shown in FIG. 4.

FIG. 6 is a schematic cross-sectional view of the display device along the VI-VI line of FIG. 5.

FIG. 7 is a schematic enlarged plan view of segments according to a second embodiment.

FIG. 8 is a schematic cross-sectional view of a display device along the VIII-VIII line of FIG. 7.

FIG. 9 is a diagram showing a touch detection system according to a third embodiment.

FIG. 10 is a schematic cross-sectional view showing an example of the configuration of a display device comprising a detection electrode.

FIG. 11 is a schematic cross-sectional view showing another example of the configuration of the display device comprising the detection electrode.

FIG. 12 is a schematic plan view of segments according to the third embodiment.

FIG. 13 is a schematic plan view of the detection electrodes according to the third embodiment.

FIG. 14 is a schematic enlarged plan view showing an example of a configuration which could be applied to the segments according to the third embodiment.

FIG. 15 is a schematic enlarged plan view showing another example of a configuration which could be applied to the segments according to the third embodiment.

FIG. 16 is a schematic enlarged plan view showing yet another example of a configuration which could be applied to the segments according to the third embodiment.

FIG. 17 is a schematic plan view of segments according to a fourth embodiment.

FIG. 18 is a schematic plan view of detection electrodes according to the fourth embodiment.

FIG. 19 is a schematic enlarged plan view showing an example of a configuration which could be applied to the segments according to the fourth embodiment.

FIG. 20 is a schematic enlarged plan view showing another example of a configuration which could be applied to the segments according to the fourth embodiment.

FIG. 21 is a schematic enlarged plan view showing yet another example of a configuration which could be applied to the segments according to the fourth embodiment.

### DETAILED DESCRIPTION

In general, according to one embodiment, a display device comprises a plurality of display elements each of which includes a lower electrode, an upper electrode facing the lower electrode, and an organic layer provided between the lower electrode and the upper electrode and emitting light based on a potential difference between the lower electrode and the upper electrode, a rib which has a plurality of pixel apertures overlapping the display elements, respectively, and a partition which includes a conductive lower portion provided on the rib and an upper portion protruding from a side surface of the lower portion and surrounds each of the display elements. Further, the partition is divided into a plurality of segments for detecting an object which is in contact with or close to a display area including the display elements.

The above configuration can realize the reduction in the manufacturing cost of a display device comprising the function of a touch sensor or the improvement of the display quality of such a display device.

Embodiments will be described with reference to the accompanying drawings.

The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes, etc., of the respective parts are illustrated schematically in the drawings, rather than as an accurate representation of what is implemented. However, such schematic illustration is merely exemplary, and in no way restricts the interpretation of the invention. In addition, in the specification and drawings, structural elements which function in the same or a similar manner to those described in connection with preceding drawings are denoted by like reference numbers, detailed description thereof being omitted unless necessary.

In the drawings, in order to facilitate understanding, an X-axis, a Y-axis and a Z-axis orthogonal to each other are shown depending on the need. A direction parallel to the X-axis is referred to as an X-direction. A direction parallel to the Y-axis is referred to as a Y-direction. A direction parallel to the Z-axis is referred to as a Z-direction. The Z-direction is the normal direction of a plane including the X-direction and the Y-direction. When various elements are viewed parallel to the Z-direction, the appearance is defined as a plan view.

The display device of each embodiment is an organic electroluminescent display device comprising an organic light emitting diode (OLED) as a display element, and could be mounted on various types of electronic devices such as a television, a personal computer, a vehicle-mounted device, a tablet, a smartphone, a mobile phone and a wearable terminal.

### First Embodiment

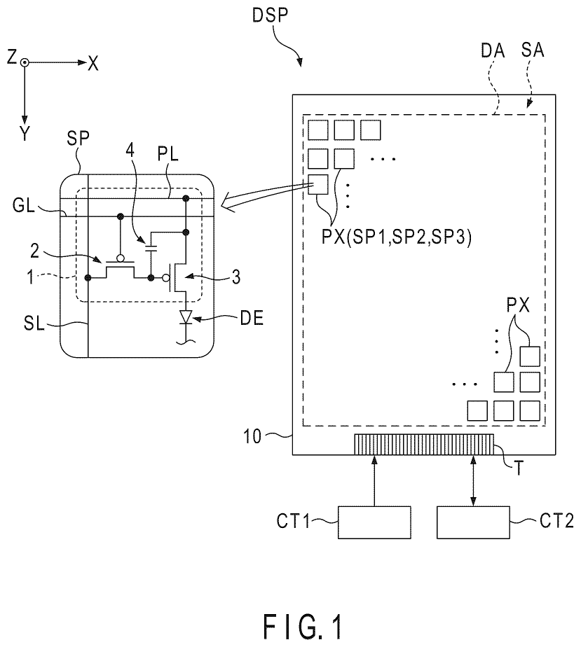

FIG. 1 is a diagram showing a configuration example of a display device DSP according to a first embodiment. The display device DSP comprises an insulating substrate 10. The substrate 10 has a display area DA which displays an image, and a surrounding area SA around the display area DA. The substrate 10 may be glass or a resinous film having flexibility.

In the embodiment, the substrate 10 is rectangular as seen in plan view. It should be noted that the shape of the substrate 10 in plan view is not limited to a rectangle and may be another shape such as a square, a circle or an oval.

The display area DA comprises a plurality of pixels PX arrayed in matrix in an X-direction and a Y-direction. Each pixel includes a plurality of subpixels SP which display different colors. This embodiment assumes a case where each pixel PX includes a blue subpixel SP1, a green subpixel SP2 and a red subpixel SP3. However, each pixel PX may include a subpixel SP which exhibits another color such as white in addition to subpixels SP1, SP2 and SP3 or instead of one of subpixels SP1, SP2 and SP3.

Each subpixel SP comprises a pixel circuit 1 and a display element DE driven by the pixel circuit 1. The pixel circuit 1 comprises a pixel switch 2, a drive transistor 3 and a capacitor 4. Each of the pixel switch 2 and the drive transistor 3 is, for example, a switching element consisting of a thin-film transistor.

A plurality of scanning lines GL which supply scanning signals to the pixel circuits 1 of subpixels SP, a plurality of signal lines SL which supply video signals to the pixel circuits 1 of subpixels SP and a plurality of power lines PL are provided in the display area DA. In the example of FIG. 1, the scanning lines GL and the power lines PL extend in the X-direction, and the signal lines SL extend in the Y-direction.

The gate electrode of the pixel switch 2 is connected to the scanning line GL. The source electrode of the pixel switch 2 is connected to the signal line SL. The drain electrode of the pixel switch 2 is connected to the gate electrode of the drive transistor 3 and the capacitor 4.

The source electrode of the drive transistor 3 is connected to the power line PL and the capacitor 4. The drain electrode of the drive transistor 3 is connected to the display element DE (the lower electrode LE1, LE2 or LE3 described later). In the embodiment, the drive transistor 3 consists of a thin-film transistor including a p-type semiconductor.

It should be noted that the configuration of the pixel circuit 1 is not limited to the example shown in the figure. For example, the pixel circuit 1 may comprise more thin-film transistors and capacitors.

The display device DSP further comprises a terminal portion T provided in the surrounding area SA. For example, a flexible printed circuit which applies voltage and signals for driving the display device DSP is connected to the terminal portion T.

The display device DSP further comprises a display controller CT1 which controls the image display of the display area DA and a detection controller CT2 which detects touch operation for the display area DA. Each of the display controller CT1 and the detection controller CT2 is, for example, an IC mounted on the flexible printed circuit described above. As another example, the display controller CT1 and the detection controller CT2 may be mounted in the surrounding area SA.

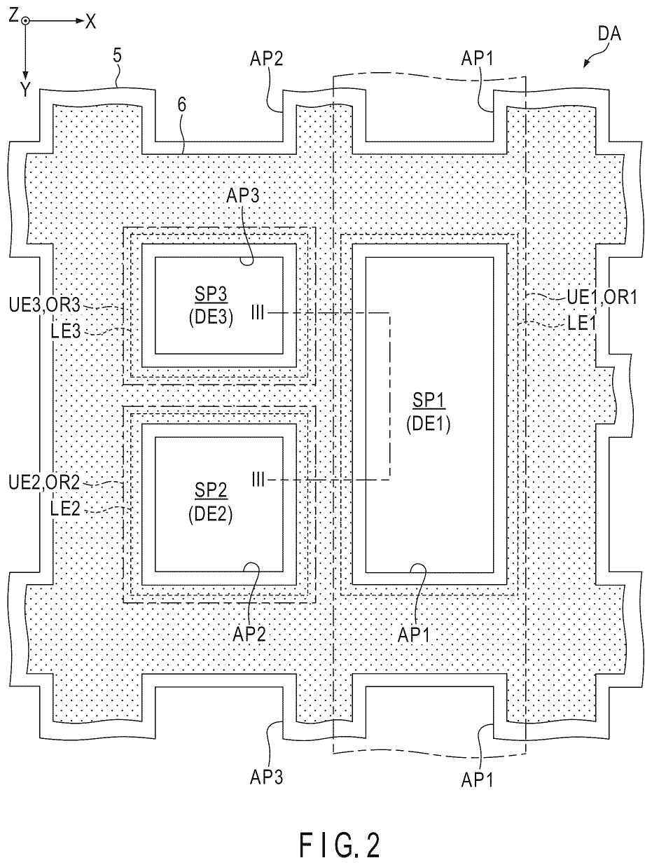

FIG. 2 is a schematic plan view showing an example of the layout of subpixels SP1, SP2 and SP3. In the example of FIG. 2, each of subpixels SP2 and SP3 is adjacent to subpixel SP1 in the X-direction. Further, subpixels SP2 and SP3 are arranged in the Y-direction.

When subpixels SP1, SP2 and SP3 are provided in line with this layout, a column in which subpixels SP2 and SP3 are alternately provided in the Y-direction and a column in which a plurality of subpixels SP1 are repeatedly provided in the Y-direction are formed in the display area DA. These columns are alternately arranged in the X-direction. It should be noted that the layout of subpixels SP1, SP2 and SP3 is not limited to the example of FIG. 2.

A rib 5 is provided in the display area DA. The rib 5 has pixel apertures AP1, AP2 and AP3 in subpixels SP1, SP2 and SP3, respectively. In the example of FIG. 2, the pixel aperture AP1 is larger than the pixel aperture AP2. The pixel aperture AP2 is larger than the pixel aperture AP3. Thus, among subpixels SP1, SP2 and SP3, the aperture ratio of subpixel SP1 is the greatest, and the aperture ratio of subpixel SP3 is the least.

Subpixel SP1 comprises a lower electrode LE1, an upper electrode UE1 and an organic layer OR1 overlapping the pixel aperture AP1. Subpixel SP2 comprises a lower electrode LE2, an upper electrode UE2 and an organic layer OR2 overlapping the pixel aperture AP2. Subpixel SP3 comprises a lower electrode LE3, an upper electrode UE3 and an organic layer OR3 overlapping the pixel aperture AP3.

Of the lower electrode LE1, the upper electrode UE1 and the organic layer OR1, the portions which overlap the pixel aperture AP1 constitute the display element DE1 of subpixel SP1. Of the lower electrode LE2, the upper electrode UE2 and the organic layer OR2, the portions which overlap the pixel aperture AP2 constitute the display element DE2 of subpixel SP2. Of the lower electrode LE3, the upper electrode UE3 and the organic layer OR3, the portions which overlap the pixel aperture AP3 constitute the display element DE3 of subpixel SP3. Each of the display elements DE1, DE2 and DE3 may further include a cap layer as described later. The rib 5 surrounds each of these display elements DE1, DE2 and DE3.

A conductive partition 6 is provided above the rib 5. The partition 6 overlaps the rib 5 as a whole and has the same planar shape as the rib 5. In other words, the partition 6 has an aperture in each of subpixels SP1, SP2 and SP3. From another viewpoint, each of the rib 5 and the partition 6 has a grating shape as seen in plan view, and surrounds each of the display elements DE1, DE2 and DE3. The partition 6 functions as lines which apply common voltage to the upper electrodes UE1, UE2 and UE3.

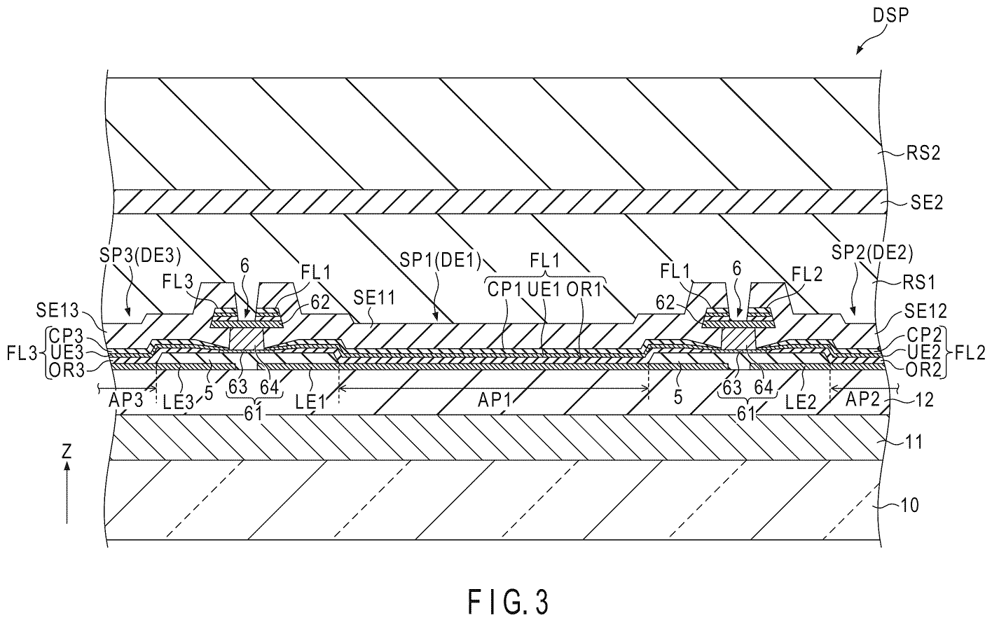

FIG. 3 is a schematic cross-sectional view of the display device DSP along the III-III line of FIG. 2. A circuit layer 11 is provided on the substrate 10 described above. The circuit layer 11 includes various circuits and lines such as the pixel circuits 1, scanning lines GL, signal lines SL and power lines PL shown in FIG. 1. The circuit layer 11 is covered with an organic insulating layer 12. The organic insulating layer 12 functions as a planarization film which planarizes the irregularities formed by the circuit layer 11.

The lower electrodes LE1, LE2 and LE3 are provided on the organic insulating layer 12. The rib 5 is provided on the organic insulating layer 12 and the lower electrodes LE1, LE2 and LE3. The end portions of the lower electrodes LE1, LE2 and LE3 are covered with the rib 5. Although not shown in the section of FIG. 3, the lower electrodes LE1, LE2 and LE3 are connected to the respective pixel circuits 1 (the drain electrodes of the drive transistors 3 shown in FIG. 1) of the circuit layer 11 through respective contact holes provided in the organic insulating layer 12.

The partition 6 includes a conductive lower portion 61 provided on the rib 5 and an upper portion 62 provided on the lower portion 61. The upper portion 62 has a width greater than that of the lower portion 61. By this configuration, the both end portions of the upper portion 62 protrude relative to the side surfaces of the lower portion 61. This shape of the partition 6 is called an overhang shape.

In the example of FIG. 3, the lower portion 61 has a bottom layer 63 provided on the rib 5, and a stem layer 64 provided on the bottom layer 63. For example, the bottom layer 63 is formed so as to be thinner than the stem layer 64. In the example of FIG. 3, the both end portions of the bottom layer 63 protrude from the side surfaces of the stem layer 64.

The organic layer OR1 covers the lower electrode LE1 through the pixel aperture AP1. The upper electrode UE1 covers the organic layer OR1 and faces the lower electrode LE1. The organic layer OR2 covers the lower electrode LE2 through the pixel aperture AP2. The upper electrode UE2 covers the organic layer OR2 and faces the lower electrode LE2. The organic layer OR3 covers the lower electrode LE3 through the pixel aperture AP3. The upper electrode UE3 covers the organic layer OR3 and faces the lower electrode LE3. The upper electrodes UE1, UE2 and UE3 are in contact with the side surfaces of the lower portions 61 of the partition 6.

The display element DE1 includes a cap layer CP1 which covers the upper electrode UE1. The display element DE2 includes a cap layer CP2 which covers the upper electrode UE2. The display element DE3 includes a cap layer CP3 which covers the upper electrode UE3. The cap layers CP1, CP2 and CP3 function as optical adjustment layers which improve the extraction efficiency of the light emitted from the organic layers OR1, OR2 and OR3, respectively.

In the following explanation, a multilayer body including the organic layer OR1, the upper electrode UE1 and the cap layer CP1 is called a stacked film FL1. A multilayer body including the organic layer OR2, the upper electrode UE2 and the cap layer CP2 is called a stacked film FL2. A multilayer body including the organic layer OR3, the upper electrode UE3 and the cap layer CP3 is called a stacked film FL3.

The stacked film FL1 is partly located on the upper portion 62. This portion is spaced apart from, of the stacked film FL1, the portion located around the partition 6 (in other words, the portion which constitutes the display element DE1). Similarly, the stacked film FL2 is partly located on the upper portion 62. This portion is spaced apart from, of the stacked film FL2, the portion located around the partition 6 (in other words, the portion which constitutes the display element DE2). Further, the stacked film FL3 is partly located on the upper portion 62. This portion is spaced apart from, of the stacked film FL3, the portion located around the partition 6 (in other words, the portion which constitutes the display element DE3).

Sealing layers SE11, SE12 and SE13 are provided in subpixels SP1, SP2 and SP3, respectively. The sealing layer SE11 continuously covers the cap layer CP1 and the partition 6 around subpixel SP1. The sealing layer SE12 continuously covers the cap layer CP2 and the partition 6 around subpixel SP2. The sealing layer SE13 continuously covers the cap layer CP3 and the partition 6 around subpixel SP3.

In the example of FIG. 3, the stacked film FL1 and sealing layer SE11 located on the partition 6 between subpixels SP1 and SP2 are spaced apart from the stacked film FL2 and sealing layer SE12 located on this partition 6. The stacked film FL1 and sealing layer SE11 located on the partition 6 between subpixels SP1 and SP3 are spaced apart from the stacked film FL3 and sealing layer SE13 located on this partition 6.

The sealing layers SE11, SE12 and SE13 are covered with a resin layer RS1. The resin layer RS1 is covered with a sealing layer SE2. The sealing layer SE2 is covered with a resin layer RS2. The resin layers RS1 and RS2 and the sealing layer SE2 are continuously provided in at least the entire display area DA and partly extend in the surrounding area SA as well.

A cover member such as a polarizer, a protective film or a cover glass may be further provided above the resin layer RS2. This cover member may be attached to the resin layer RS2 via, for example, an adhesive layer such as an optical clear adhesive (OCA).

The organic insulating layer 12 is formed of an organic insulating material such as polyimide. Each of the rib 5 and the sealing layers SE11, SE12, SE13 and SE2 is formed of an inorganic insulating material such as silicon nitride (SiNx), silicon oxide (SiOx), silicon oxynitride (SiON) or aluminum oxide (Al₂O₃). For example, the rib 5 is formed of silicon oxynitride, and each of the sealing layers SE11, SE12, SE13 and SE2 is formed of silicon nitride. Each of the resin layers RS1 and RS2 is formed of, for example, a resinous material (organic insulating material) such as epoxy resin or acrylic resin.

Each of the lower electrodes LE1, LE2 and LE3 has a reflective layer, and a pair of conductive oxide layers covering the upper and lower surfaces of the reflective layer. The reflective layer can be formed of, for example, a metal material having excellent light reflectivity, such as silver. Each conductive oxide layer can be formed of, for example, a transparent conductive oxide such as indium tin oxide (ITO), indium zinc oxide (IZO) or indium gallium zinc oxide (IGZO).

Each of the upper electrodes UE1, UE2 and UE3 is formed of, for example, a metal material such as an alloy of magnesium and silver (MgAg). For example, the lower electrodes LE1, LE2 and LE3 correspond to anodes, and the upper electrodes UE1, UE2 and UE3 correspond to cathodes.

Each of the organic layers OR1, OR2 and OR3 consists of a plurality of thin films including a light emitting layer. For example, each of the organic layers OR1, OR2 and OR3 comprises a structure in which a hole injection layer, a hole transport layer, an electron blocking layer, a light emitting layer, a hole blocking layer, an electron transport layer and an electron injection layer are stacked in order in a Z-direction. It should be noted that each of the organic layers OR1, OR2 and OR3 may comprise another structure such as a tandem structure including a plurality of light emitting layers.

Each of the cap layers CP1, CP2 and CP3 comprises, for example, a multilayer structure in which a plurality of transparent layers are stacked. These transparent layers could include a layer formed of an inorganic material and a layer formed of an organic material. The transparent layers have refractive indices different from each other. For example, the refractive indices of these transparent layers are different from the refractive indices of the upper electrodes UE1, UE2 and UE3 and the refractive indices of the sealing layers SE11, SE12 and SE13. It should be noted that at least one of the cap layers CP1, CP2 and CP3 may be omitted.

Each of the bottom layer 63 and stem layer 64 of the partition 6 is formed of, for example, a metal material. For the metal material of the bottom layer 63, for example, molybdenum, titanium, titanium nitride (TiN), a molybdenum-tungsten alloy (MoW) or a molybdenum-niobium alloy (MoNb) can be used. For the metal material of the stem layer 64, for example, aluminum, an aluminum-neodymium alloy (AlNd), an aluminum-yttrium alloy (AlY) or an aluminum-silicon alloy (AlSi) can be used. It should be noted that at least one of the bottom layer 63 and the stem layer 64 may comprise a multilayer structure consisting of a plurality of layers. The stem layer 64 may include a layer formed of an insulating material.

For example, the upper portion 62 of the partition 6 comprises a multilayer structure consisting of a lower layer formed of a metal material and an upper layer formed of conductive oxide. For the metal material forming the lower layer, for example, titanium, titanium nitride, molybdenum, tungsten, a molybdenum-tungsten alloy or a molybdenum-niobium alloy may be used. For the conductive oxide forming the upper layer, for example, ITO or IZO may be used. It should be noted that the upper portion 62 may comprise a single-layer structure of a metal material. The upper portion 62 may further include a layer formed of an insulating material.

Common voltage is applied to the partition 6. This common voltage is applied to each of the upper electrodes UE1, UE2 and UE3 which are in contact with the side surfaces of the lower portions 61. Pixel voltage is applied to the lower electrodes LE1, LE2 and LE3 through the pixel circuits 1 provided in subpixels SP1, SP2 and SP3, respectively, based on the video signals of the signal lines SL.

The organic layers OR1, OR2 and OR3 emit light based on the application of voltage. Specifically, when a potential difference is formed between the lower electrode LE1 and the upper electrode UE1, the light emitting layer of the organic layer OR1 emits light in a blue wavelength range. When a potential difference is formed between the lower electrode LE2 and the upper electrode UE2, the light emitting layer of the organic layer OR2 emits light in a green wavelength range. When a potential difference is formed between the lower electrode LE3 and the upper electrode UE3, the light emitting layer of the organic layer OR3 emits light in a red wavelength range.

As another example, the light emitting layers of the organic layers OR1, OR2 and OR3 may emit light exhibiting the same color (for example, white). In this case, the display device DSP may comprise color filters which convert the light emitted from the light emitting layers into light exhibiting colors corresponding to subpixels SP1, SP2 and SP3. The display device DSP may comprise a layer including quantum dots which generate light exhibiting colors corresponding to subpixels SP1, SP2 and SP3 by the excitation caused by the light emitted from the light emitting layers.

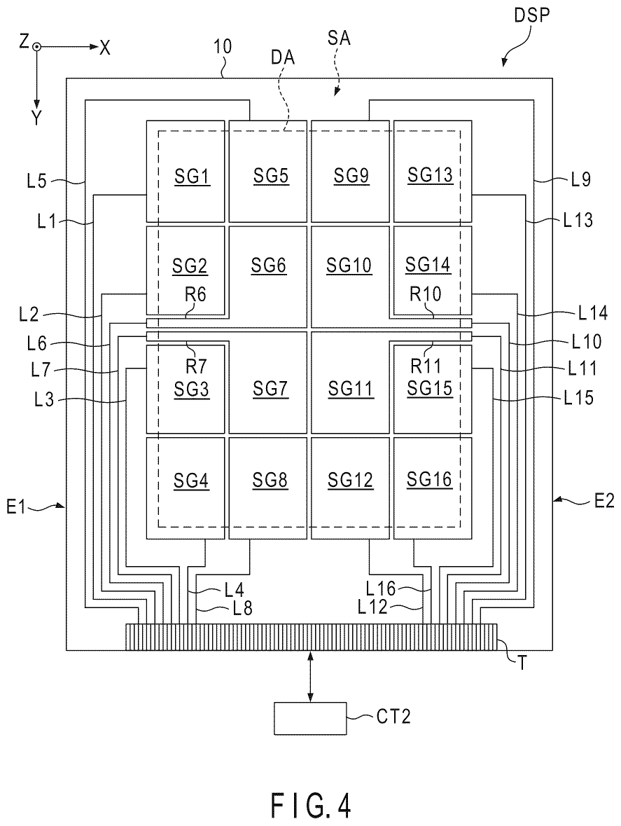

FIG. 4 is a schematic plan view showing elements for detecting touch operation for the display area DA. The display device DSP comprises a plurality of segments SG which function as electrodes for a touch sensor. These segments SG consist of the partition 6 and the upper electrodes UE1, UE2 and UE3.

In the example of FIG. 4, 16 segments SG (SG1 to SG16) which overlap the display area DA are provided in a matrix consisting of 4 columns×4 rows. It should be noted that the number of segments SG or the layout of the segments SG is not limited to this example.

The segments SG1 to SG16 are connected to the terminal portion T via leads L1 to L16 provided in the surrounding area SA, respectively. In the example of FIG. 4, the leads L1 to L3 and L5 to L7 of the segments SG1 to SG3 and SG5 to SG7 pass through the area located between the display area DA and the left end portion E1 of the substrate 10. The leads L9 to L11 and L13 to L15 of the segments SG9 to SG11 and SG13 to SG15 pass through the area located between the display area DA and the right end portion E2 of the substrate 10 in the figure. The leads L4, L8, L12 and L16 of the segments SG4, SG8, SG12 and SG16 are provided between the display area DA and the terminal portion T as a whole.

The segments SG6, SG7, SG10 and SG11 are surrounded by the other segments SG. To enable the connection between these segments SG6, SG7, SG10 and SG11 and the leads L6, L7, L10 and L11, relay portions R6, R7, R10 and R11 are provided in the display area DA in the example of FIG. 4.

The relay portions R6, R7, R10 and R11 connect the segments SG6, SG7, SG10 and SG11 to the leads L6, L7, L10 and L11, respectively. The relay portions R6 and R7 are located between the segments SG2 and SG3. The relay portions R10 and R11 are located between the segments SG14 and SG15.

The detection controller CT2 supplies a drive signal to the segments SG1 to SG16 via the leads L1 to L16 with a predetermined period. By this drive signal, the capacity of the segments SG1 to SG16 themselves is charged.

After the supply of the drive signal, the detection controller CT2 reads a detection signal (output voltage) from the segments SG1 to SG16 via the leads L1 to L16. The detection signal corresponds to, for example, the amount of charge stored in the capacity of the segments SG1 to SG16 themselves.

Among the segments SG1 to SG16 arrayed in an X-Y plane (detection surface), the value of the detection signal differs between segments SG which are close to an object such as a finger of the user and the other segments SG. Thus, the detection controller CT2 can detect location information of the object based on the detection signal of each segment SG.

When the display device DSP operates, a display period for image display and a sensor period for touch detection are repeated. In each display period, display voltage is written to each of the display elements DE1, DE2 and DE3. In each sensor period, a drive signal is supplied to the segments SG1 to SG16 and read from the segments SG1 to SG16. The display voltage written in a display period is maintained in a sensor period as well.

It should be noted that the detection system using the segments SG1 to SG16 or the operation of the display device DSP is not limited to the example shown here.

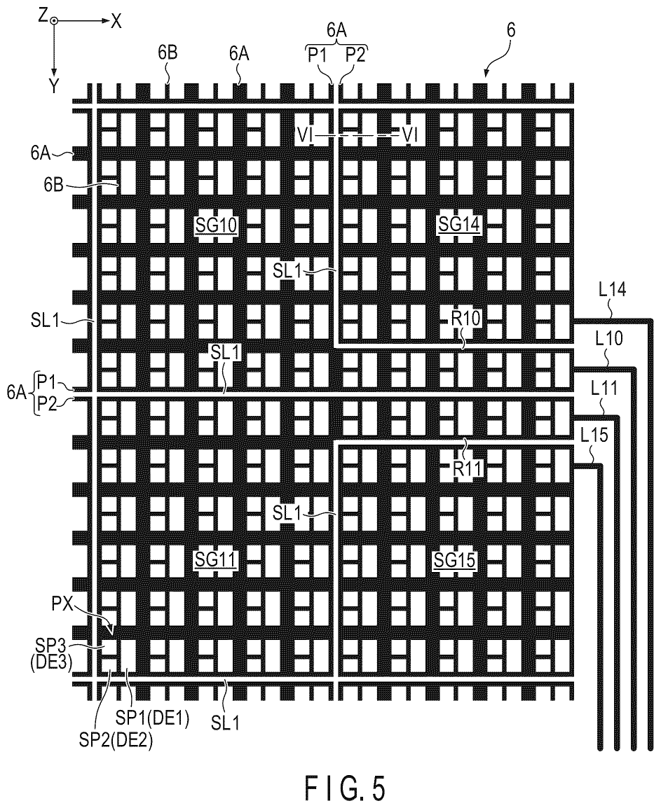

FIG. 5 is a schematic enlarged plan view of the segments SG. This figure shows the segments SG10, SG11, SG14 and SG15 and part of the leads L10, L11, L14 and L15.

In the example of FIG. 5, the partition 6 has two types of partitions 6A and 6B (first and second partitions). The width of the partition 6A is greater than that of the partition 6B.

The partition 6A has a grating shape which includes a plurality of portions extending in the X-direction and a plurality of portions extending in the Y-direction. In the example of FIG. 5, the partition 6A surrounds each pixel PX consisting of subpixels SP1, SP2 and SP3. The partition 6B is provided between subpixels SP1, SP2 and SP3 (the display elements DE1, DE2 and DE3) included in each cell of the grating of the partition 6A.

It should be noted that the configuration of the partition 6A or 6B is not limited to the example shown in FIG. 5. For example, the partition 6A may have a grating shape which surrounds two or more pixels PX.

The segments SG1 to SG16 are divided by slits SL1. In the example of FIG. 5, the slits SL1 are provided in the partition 6A as a whole. In other words, each slit SL1 divides the partition 6A into a first part P1 and a second part P2.

The relay portions R10 and R11 consist of the partition 6 and the upper electrodes UE1, UE2 and UE3 in a manner similar to that of the segments SG. The same configuration is applied to the relay portions R6 and R7. These relay portions R6, R7, R10 and R11 are divided from the surrounding segments SG2, SG3, SG14 and SG15 by the slits SL1 formed in the partition 6A.

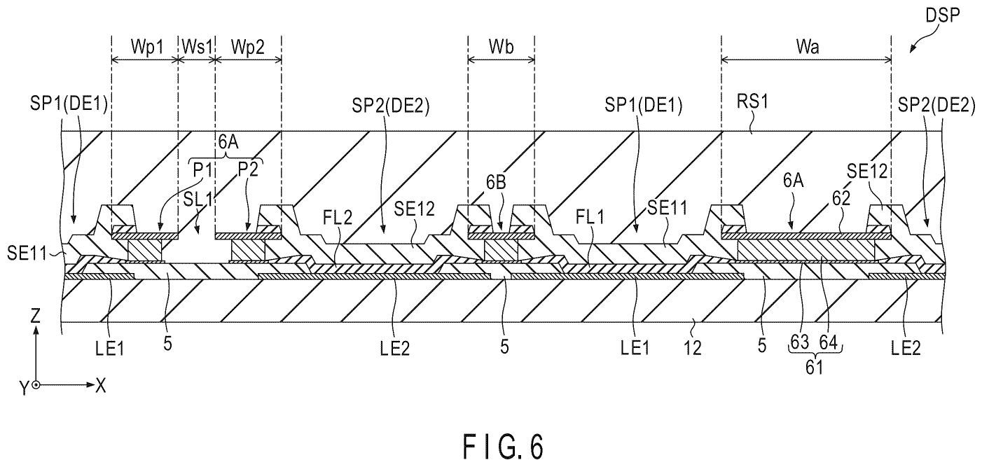

FIG. 6 is a schematic cross-sectional view of the display device DSP along the VI-VI line of FIG. 5. In this figure, the illustrations of the substrate 10, the circuit layer 11, the sealing layer SE2 and the resin layer RS2 are omitted.

The partition 6A has width Wa. The partition 6B has width Wb which is less than width Wa (Wb<Wa). In the example of FIG. 6, the width of the rib 5 under the partition 6A is greater than that of the rib 5 under the partition 6B. As another example, the widths of the rib 5 under the partitions 6A and 6B may be equal to each other.

The first part P1 of the partition 6A has width Wp1. The second part P2 of the partition 6A has width Wp2. The slit SL1 has width Ws1. In the example of FIG. 6, widths Wp1 and Wp2 are equal to each other (Wp1=Wp2). Width Ws1 is less than widths Wp1 and Wp2 (Ws1<Wp1, Wp2). For example, widths Wp1 and Wp2 are equal to width Wb (Wp1=Wp2=Wb). The sum of widths Wp1, Wp2 and Ws1 is equal to width Wa (Wp1+Wp2+Ws1=Wa).

The relationships of widths Wa, Wb, Wp1, Wp2 and Ws1 are not limited to the example shown here. As another example, widths Wp1, Wp2 and Wb may be different from each other. Width Ws1 may be greater than or equal to widths Wp1 and Wp2.

All of the partition 6A, the partition 6B, the first part P1 and the second part P2 have overhang shapes. In other words, the upper portion 62 of each of the partition 6A, the partition 6B, the first part P1 and the second part P2 protrudes from the both side surfaces of the stem layer 64.

In the example of FIG. 6, the rib 5 located under the first part P1 and the second part P2 is continuous. Thus, the rib 5 is not divided in the slit SL1. From another viewpoint, the slit SL1 overlaps the rib 5 in the Z-direction. In the example of FIG. 6, the slit SL1 does not overlap the lower electrode LE1, LE2 or LE3 in the Z-direction.

None of the stacked films FL1, FL2 and FL3 and the sealing layers SE11, SE12 and SE13 is provided in the slit SL1. The slit SL1 is filled with the resin layer RS1. The resin layer RS1 is in contact with the rib 5 in the slit SL1.

It should be noted that the rib 5 may be divided in the slit SL1. One or some of the stacked films FL1, FL2 and FL3 and the sealing layers SE11, SE12 and SE13 may be provided in the slit SL1.

In the embodiment explained above, the partition 6 and the upper electrodes UE1, UE2 and UE3 for applying common voltage to the display elements DE1, DE2 and DE3 also function as the electrodes of a touch sensor. This configuration can reduce the thickness of the display device DSP compared to a case where electrodes for a touch sensor are separately provided. In addition, the number of processes for manufacturing the display device DSP can be reduced. As a result, the manufacturing costs of the display device DSP can be reduced.

The layers which constitute each of the stacked films FL1, FL2 and FL3 are formed by vapor deposition. The partition 6 having an overhang shape also functions to divide these stacked films FL1, FL2 and FL3 at the time of vapor deposition. This configuration enables the realization of the configuration of individually sealing the stacked films FL1, FL2 and FL3 by the partition 6 and the sealing layers SE11, SE12 and SE13, respectively, as shown in FIG. 3. In this configuration, moisture incursion into the stacked films FL1, FL2 and FL3 can be effectively prevented. In addition, even if moisture enters one of the stacked films FL1, FL2 and FL3, the surrounding stacked films are not easily affected by the moisture incursion.

An electronic device on which the display device DSP is mounted may comprise an antenna for near field communication (NFC). This antenna is provided so as to, for example, face the rear side of the display device DSP (in other words, the lower surface of the substrate 10 shown in FIG. 3) and wirelessly communicates with another electronic device through the display device DSP.

The partition 6 and the upper electrodes UE1, UE2 and UE3 provided in the display area DA constitute a common electrode to which common voltage is applied. At the time of wireless communication, eddy current is generated in the common electrode by a magnetic field formed by the antenna described above. By this eddy current, a magnetic field having a direction which negates the above magnetic field is formed, and the signal strength is attenuated. Thus, when wireless communication is performed via the display device DSP, the communication sensitivity could be decreased.

In this embodiment, the common electrode which consists of the partition 6 and the upper electrodes UE1, UE2 and UE3 is divided into a plurality of segments SG by the slits SL1. In this case, eddy current is suppressed compared to a case where the common electrode is not divided, and thus, the reduction in communication sensitivity can be diminished.

An electronic device on which the display device DSP is mounted may comprise an optical sensor such as an illumination sensor which detects external light. When such an optical sensor is provided on the rear side of the display device DSP, translucency is required in the display device DSP.

However, each of the lower electrodes LE1, LE2 and LE3 includes the reflective layer described above. In addition, the partition 6 which is at least partly formed of a metal material has light-shielding properties. For this reason, if the lower electrodes LE1, LE2 and LE3 and the partition 6 are formed in the entire display area DA, the light which is made incident on the display surface of the display device DSP could be mostly reflected or blocked without being transmitted to the rear side.

In this embodiment, the partition 6 is divided by the slits SL1. As shown in FIG. 6, the slit SL1 does not overlap the lower electrode LE1, LE2 or LE3. Thus, part of the external light which enters the display area DA can pass through the slits SL1 to the lower side of the display device DSP. By this configuration, the translucency of the display device DSP can be increased.

In the embodiment, the drive transistor 3 shown in FIG. 1 consists of a thin-film transistor including a p-type semiconductor. The drain electrode of the drive transistor 3 is connected to the display element DE (the lower electrode LE1, LE2 or LE3). In this configuration, even if the potential of the partition 6 and the upper electrodes UE1, UE2 and UE3 constituting the segments SG for touch detection is changed by the effect of an object which is in contact with or close to the display area DA, the voltage retained by the capacitor 4 is not easily affected. Thus, stable image display is possible.

Hereinafter, this specification explains the second to fourth embodiments of the display device DSP. In these embodiments, to configurations which are not particularly referred to, configurations similar to those of the first embodiment can be applied.

### Second Embodiment

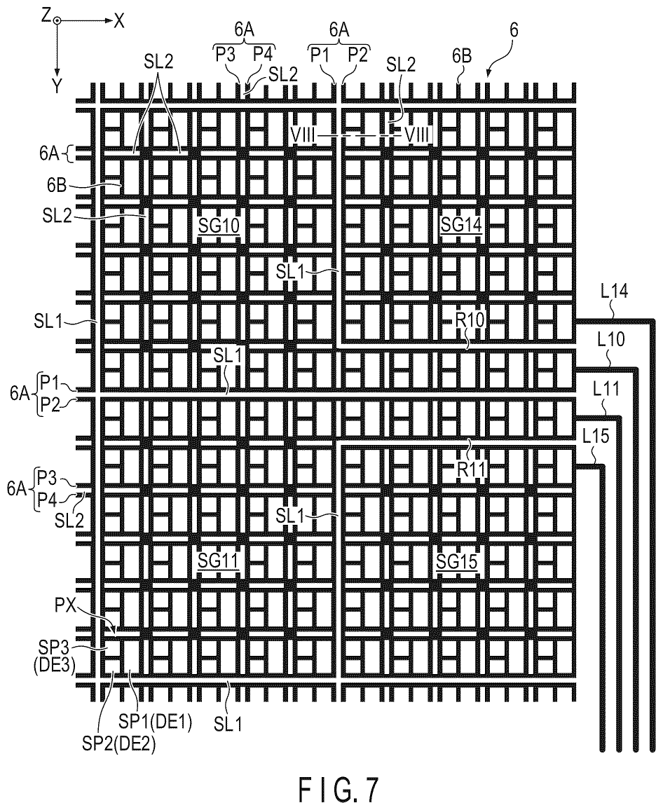

FIG. 7 is a schematic enlarged plan view of segments SG according to the second embodiment. This figure shows segments SG10, SG11, SG14 and SG15 and part of leads L10, L11, L14 and L15 in a manner similar to that of FIG. 5.

In this embodiment, a partition 6A has a plurality of slits SL2 (second slits) which are intermittently provided. These slits SL2 are provided in both portions extending in an X-direction and portions extending in a Y-direction in the partition 6A. In the following explanation, two parts into which the partition 6A is divided by each slit SL2 are called a third part P3 and a fourth part P4.

The slits SL2 are not provided in the intersections of the partition 6A. Thus, the length of each slit SL2 is less than or equal to the width of each cell of the grating of the partition 6A. As another example, each slit SL2 may be formed over a plurality of cells.

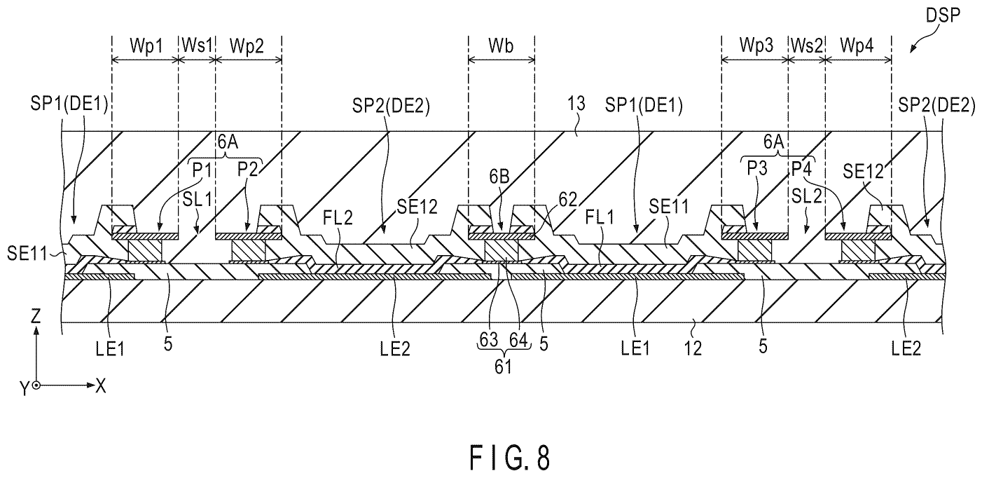

FIG. 8 is a schematic cross-sectional view of a display device DSP along the VIII-VIII line of FIG. 7. In this figure, in a manner similar to that of FIG. 6, a substrate 10, a circuit layer 11, a sealing layer SE2 and a resin layer RS2 are omitted. The configuration of the vicinity of a slit SL1 is similar to that of the example of FIG. 6.

The third part P3 of the partition 6A divided by the slit SL2 has width Wp3. The fourth part P4 of the partition 6A has width Wp4. The slit SL2 has width Ws2. For example, widths Wp3, Wp4 and Ws2 are equal to widths Wp1, Wp2 and Ws1, respectively.

Each of the third part P3 and the fourth part P4 has an overhang shape. In other words, the upper portion 62 of each of the third part P3 and the fourth part P4 protrudes from the both side surfaces of a stem layer 64.

In the example of FIG. 8, a rib 5 located under the third part P3 and the fourth part P4 is continuous. Thus, the rib 5 is not divided in the slit SL2. From another viewpoint, the slit SL2 overlaps the rib 5 in a Z-direction. In the example of FIG. 8, the slit SL2 does not overlap a lower electrode LE1, LE2 or LE3 in the Z-direction.

In a manner similar to that of the slit SL1, none of stacked films FL1, FL2 and FL3 and sealing layers SE11, SE12 and SE13 is provided in the slit SL2. The slit SL2 is filled with a resin layer RS1. The resin layer RS1 is in contact with the rib 5 in the slit SL2.

It should be noted that the rib 5 may be divided in the slit SL2. One or some of the stacked films FL1, FL2 and FL3 and the sealing layers SE11, SE12 and SE13 may be provided in the slit SL2.

If the partition 6A is divided by the slits SL1 as shown in the example of FIG. 5, the visual quality of the reflection of external light by the partition 6A may differ between the portions in which the slits SL1 are provided and the other portions. To the contrary, when the slits SL2 are provided in the partition 6A as in the case of this embodiment, the change in the visual quality of reflection by the slits SL1 can be prevented, thereby improving the display quality.

Further, the translucency of the display device DSP can be further increased by providing the slits SL2. In this configuration, when an optical sensor is provided on the rear side of the display device DSP, its sensitivity is improved.

### Third Embodiment

The third embodiment discloses a touch detection system which is different from the first embodiment, and the specific configuration for realizing the touch detection system.

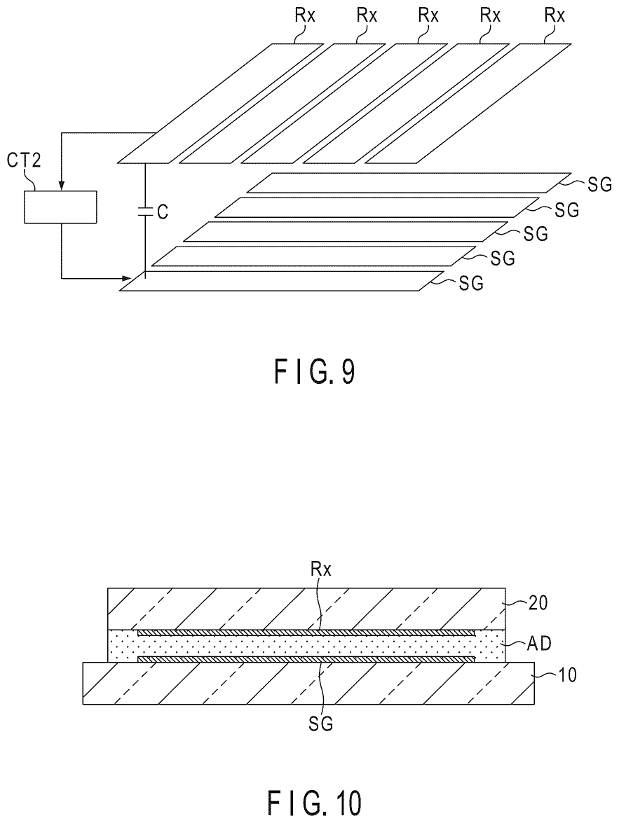

FIG. 9 is a diagram showing a touch detection system according to the third embodiment. This embodiment assumes a case where an object which is in contact with or close to a display area DA is detected using a plurality of detection electrodes Rx in addition to a plurality of segments SG.

The detection electrodes Rx are provided above the segments SG and face the segments SG via an insulating layer. A detection controller CT2 inputs a drive signal to the segments SG. At this time, a detection signal is output from the detection electrodes Rx to the detection controller CT2.

Capacitance C is formed between the detection electrodes Rx and the segments SG. When an object such as a finger of the user approaches the detection electrodes Rx, the capacitance C is affected. Based on the capacitance C, the detection signal also changes. The detection controller CT2 detects location information of the object based on this change in the detection signal.

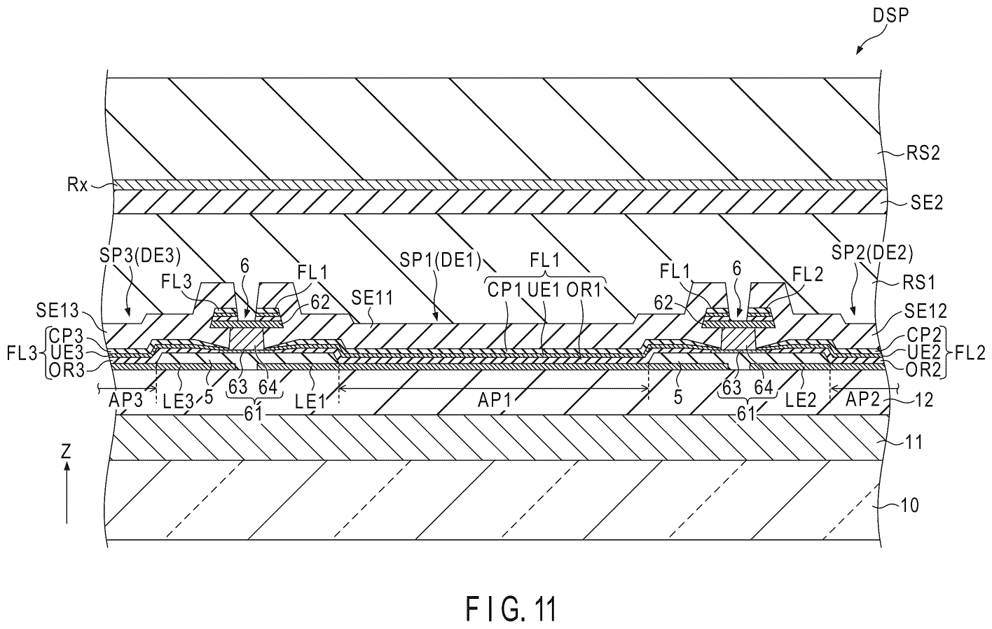

FIG. 10 is a schematic cross-sectional view showing an example of the configuration of a display device DSP comprising the detection electrode Rx. In the example of this figure, a substrate 20 (second substrate) comprising the detection electrode Rx is attached to the substrate 10 (first substrate) described above by an adhesive layer AD. In FIG. 10, the elements other than the segment SG formed in the substrate 10 are omitted.

The substrate 20 is formed of glass or a resinous film in a manner similar to that of the substrate 10. The detection electrode Rx may be provided on the lower surface of the substrate 20 as shown in the figure or may be provided on the upper surface. The adhesive layer AD is, for example, an OCA, and is formed on the resin layer RS2 shown in FIG. 3.

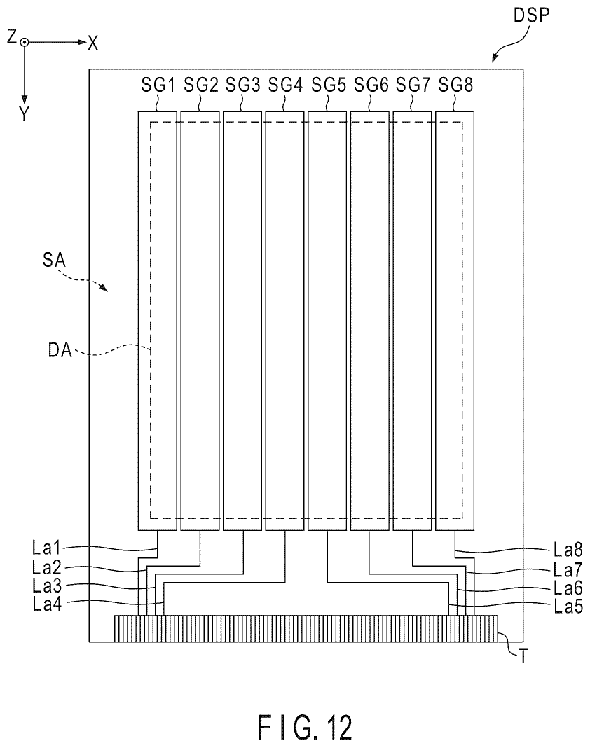

FIG. 11 is a schematic cross-sectional view showing another example of the configuration of the display device DSP comprising the detection electrode Rx. In the example of this figure, the detection electrode Rx is provided on a sealing layer SE2 and is covered with the resin layer RS2. It should be noted that the position of the detection electrode Rx is not limited to this example. The detection electrode Rx may be provided between the other layers formed in the substrate 10.

In the example of either FIG. 10 or FIG. 11, the detection electrode Rx may be formed of conductive thin metal wire. The detection electrode Rx may be formed of a transparent conductive oxide such as ITO or IZO.

FIG. 12 is a schematic plan view of the segments SG according to the embodiment. In the example of this figure, eight segments SG (SG1 to SG8) are provided in the display area DA.

Each of the segments SG1 to SG8 has a shape which is long in a Y-direction. The segments SG1 to SG8 are arranged in an X-direction. Thus, the extension direction (first direction) of the segments SG1 to SG8 is parallel to the extension direction of the signal lines SL shown in FIG. 1. For example, the shapes of the segments SG1 to SG8 are the same as each other. However, the shapes are not limited to this example. The segments SG1 to SG8 are connected to a terminal portion T via leads La1 to La8.

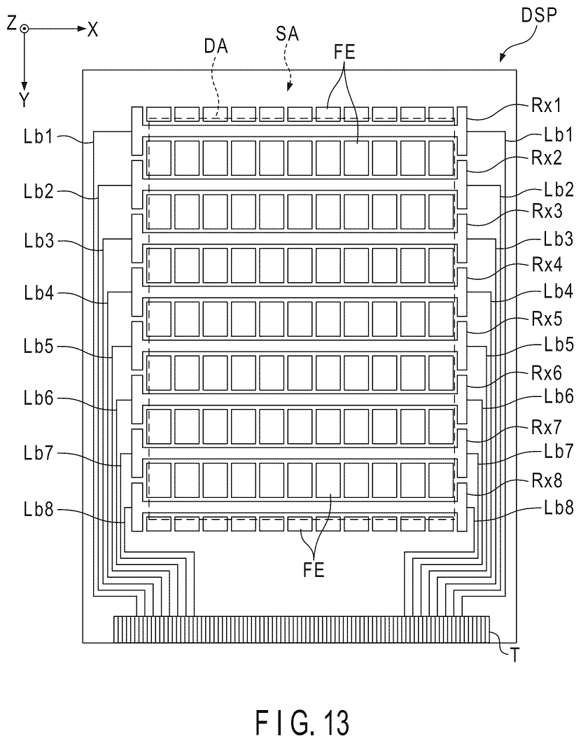

FIG. 13 is a schematic plan view of the detection electrodes Rx according to this embodiment. In the example of this figure, eight detection electrodes Rx (Rx1 to Rx8) are provided in the display area DA.

Each of the detection electrodes Rx1 to Rx8 has a shape which is long in the X-direction. The detection electrodes Rx1 to Rx8 are arranged in the Y-direction. Thus, the extension direction (second direction) of the detection electrodes Rx1 to Rx8 is parallel to the extension direction of the scanning lines GL shown in FIG. 1. In the example of FIG. 13, the both end portions of the detection electrodes Rx1 to Rx8 are located in a surrounding area SA. In the detection electrodes Rx1 to Rx8, the width of each of the both end portions in the Y-direction is enlarged compared to the portions located in the display area DA. The shapes of the detection electrodes Rx1 to Rx8 are not limited to this example. Each of the detection electrodes Rx1 to Rx8 may have a constant width over the entire part in the X-direction.

The detection electrodes Rx1 to Rx8 are connected to the terminal portion T via pairs of leads Lb1 to Lb8. As another example, the detection electrodes Rx1 to Rx8 may be connected to the terminal portion T via the respective leads Lb1 to Lb8.

When the detection electrodes Rx1 to Rx8 are formed in the substrate 20 as shown in FIG. 10, the leads Lb1 to Lb8 and the terminal portion to which these leads are connected are provided in the substrate 20. In other words, the leads La1 to La8 of the segments SG1 to SG8 may be connected to a terminal portion which is different from that of the leads Lb1 to Lb8 of the detection electrodes Rx1 to Rx8.

In the example of FIG. 13, a plurality of floating electrodes FE (dummy electrodes) spaced apart from the detection electrodes Rx1 to Rx8 are further provided. The floating electrodes FE are formed of the same material in the same layer as the detection electrodes Rx1 to Rx8.

The floating electrodes FE are arranged in the X-direction (the extension direction of each detection electrode Rx) in areas between adjacent detection electrodes Rx and in areas located on the external sides of, among the detection electrodes Rx1 to Rx8, the detection electrodes Rx1 and Rx8 located at the both ends in the Y-direction. Each floating electrode FE may be rectangular as shown in the figure, or may have another shape. The provision of these floating electrodes FE can prevent the change in the visual quality of reflection by the detection electrodes Rx1 to Rx8. Thus, the display quality can be improved.

In the configuration of the example of FIG. 12 and FIG. 13, eight segments SG and eight detection electrodes Rx are provided. It should be noted that the number of segments SG or the number of detection electrodes Rx is not limited to this example. The number of segments SG may be different from the number of detection electrodes Rx.

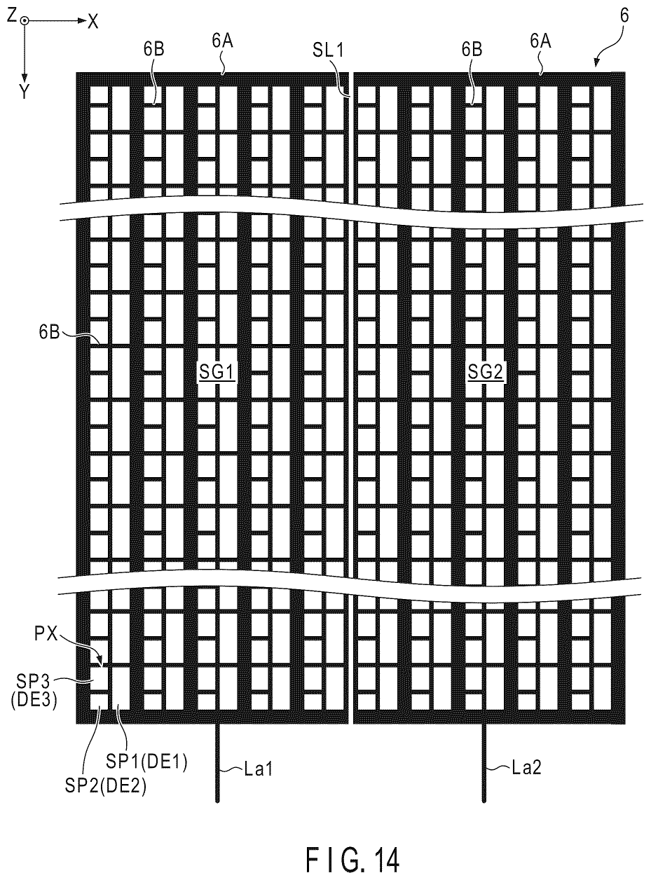

FIG. 14 is a schematic enlarged plan view showing an example of a configuration which could be applied to the segments SG according to this embodiment. This figure shows the vicinity of the boundary between the segments SG1 and SG2 and the leads La1 and La2.

In a manner similar to that of the example of FIG. 5, the segments SG1 to SG8 comprise partitions 6A and 6B and are divided by slits SL1. In the example of FIG. 14, the partition 6A is provided between pixels PX arranged in the X-direction. The partition 6B whose width is less than the partition 6A is provided between pixels PX arranged in the Y-direction and between subpixels SP1, SP2 and SP3 in each pixel PX. In this configuration, compared to the example of FIG. 5, the number of partitions 6A extending in the X-direction can be reduced, thereby increasing the width of each pixel PX in the Y-direction. As a result, the aperture ratio of subpixels SP1, SP2 and SP3 constituting each pixel PX can be increased. Thus, the display quality can be improved. For example, as shown in the figure, the slit SL1 is provided in the partition 6A and extends in the Y-direction.

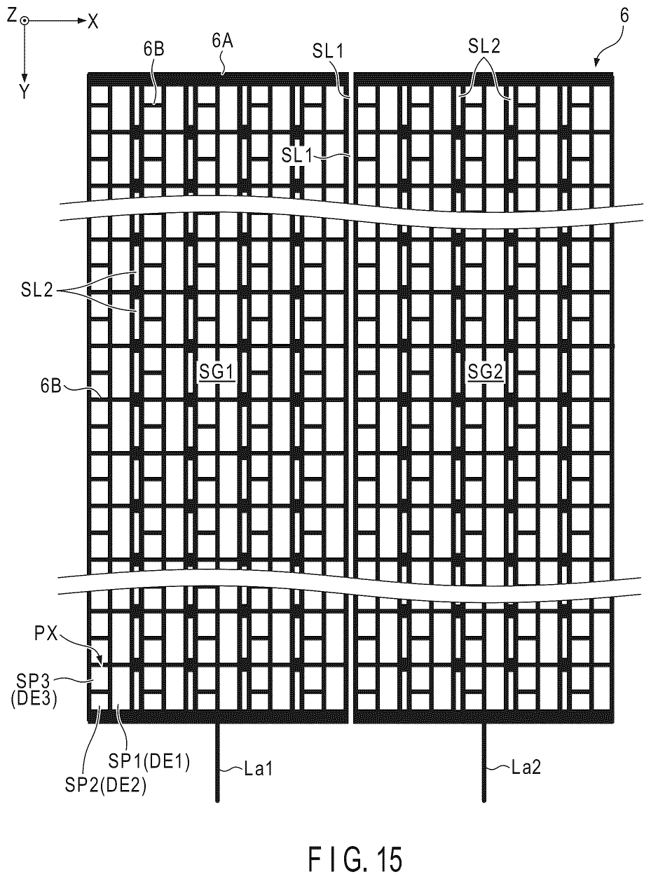

FIG. 15 is a schematic enlarged plan view showing another example of a configuration which could be applied to the segments SG according to this embodiment. In the example of this figure, the partition 6A has a plurality of slits SL2 which are intermittently provided.

Each slit SL2 has, for example, a shape which is long in the Y-direction. The slits SL2 are provided in portions extending in the Y-direction in the partition 6A. As another example, the partition 6A may have a grating shape as shown in FIG. 7, and further, the slits SL2 may be provided in both portions extending in the X-direction and portions extending in the Y-direction in the partition 6A. The provision of the slits SL2 in the partition 6A can prevent the change in the visual quality of reflection by the slits SL1, thereby improving the display quality. In addition, the translucency of the display device DSP can be increased by the slits SL2.

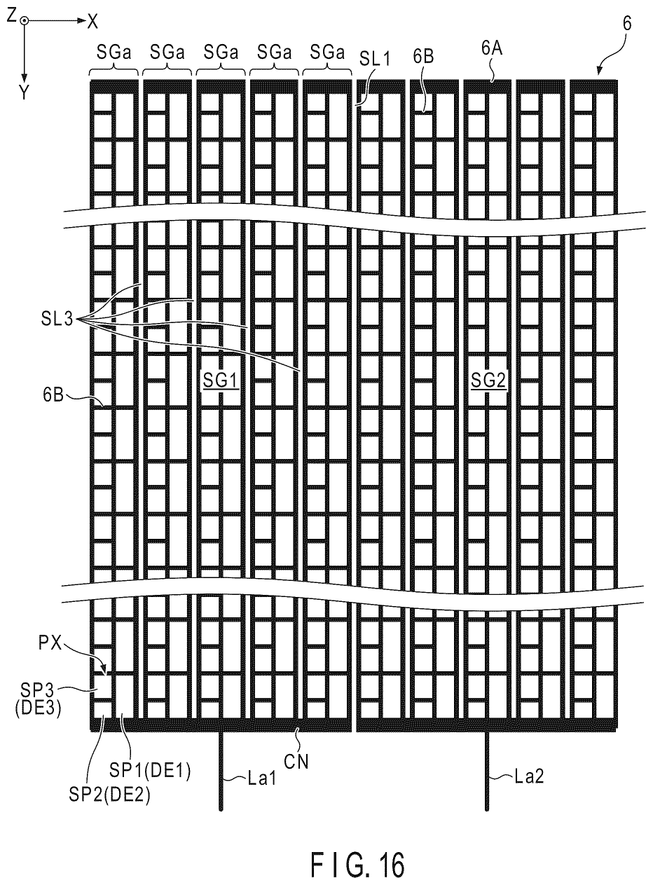

FIG. 16 is a schematic enlarged plan view showing yet another example of a configuration which could be applied to the segments SG according to this embodiment. In the example of this figure, the segment SG1 has a plurality of sub-segments SGa. Adjacent sub-segments SGa are divided by each slit SL3 (third slit). The sub-segments SGa are connected by a connection portion CN.

Each slit SL3 extends in the Y-direction in a manner similar to that of the slit SL1, and has, for example, the same width as the slit SL1. In the example of FIG. 16, each slit SL3 is provided between pixels PX which are adjacent to each other in the X-direction. In other words, one pixel column arranged in the Y-direction is provided between adjacent slits SL3. As another example, two or more pixel columns may be provided between adjacent slits SL3.

In the example of FIG. 16, the connection portion CN consists of the partition 6A extending in the X-direction and connects ends of respective sub-segment SGa in the Y-direction to each other. The lead La1 is connected to the connection portion CN. The other ends of the sub-segments SGa in the Y-direction are divided by the slits SL3. As another example, regarding both ends of the sub-segments SGa in the Y-direction, the ends may be connected to each other by the connection portion CN.

In a manner similar to that of the segment SG1, the segments SG2 to SG8 have a plurality of sub-segments SGa divided by slits SL3, and a connection portion CN connecting these sub-segments SGa. The provision of the slits SL3 in each of the segments SG1 to SG8 in this manner can also prevent the change in the visual quality of reflection by the slits SL1 and improve the display quality. In addition, the translucency of the display device DSP can be increased by the slits SL3.

### Fourth Embodiment

The fourth embodiment discloses another configuration for realizing a touch detection system similar to the third embodiment.

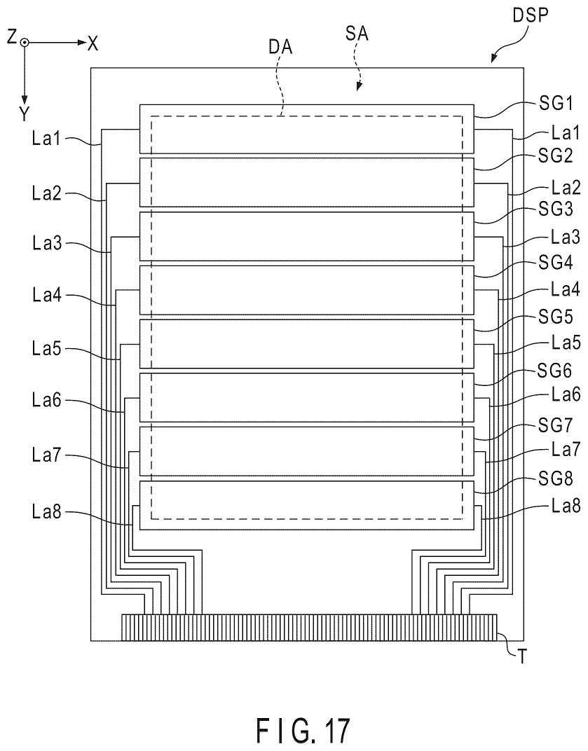

FIG. 17 is a schematic plan view of segments SG according to the fourth embodiment. In a manner similar to that of the example of FIG. 12, eight segments SG (SG1 to SG8) are provided in a display area DA. However, in the example of FIG. 17, each of the segments SG1 to SG8 has a shape which is long in an X-direction, and the segments SG1 to SG8 are arranged in a Y-direction. Thus, the extension direction (first direction) of the segments SG1 to SG8 is parallel to the extension direction of the scanning lines GL shown in FIG. 1.

The segments SG1 to SG8 are connected to a terminal portion T via pairs of leads La1 to La8. As another example, the segments SG1 to SG8 may be connected to the terminal portion T via the respective leads La1 to La8.

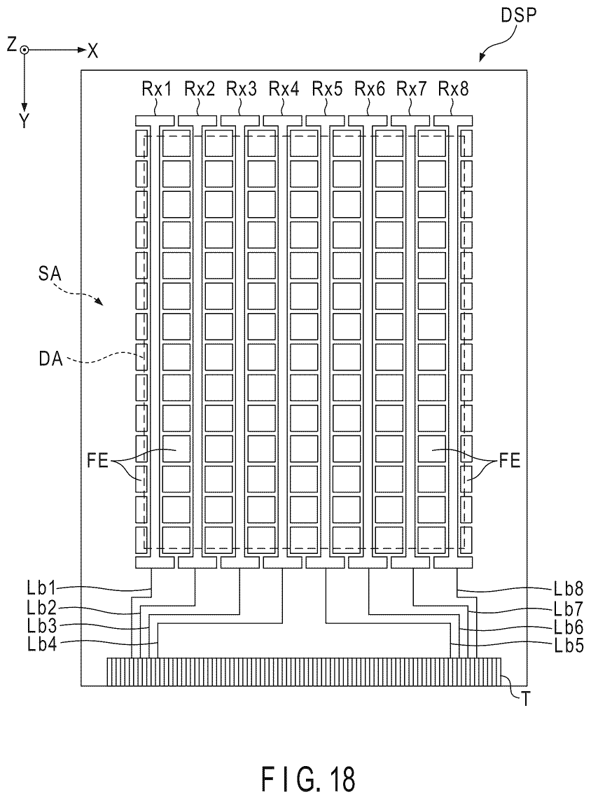

FIG. 18 is a schematic plan view of detection electrodes Rx according to this embodiment. In a manner similar to that of the example of FIG. 13, eight detection electrodes Rx (Rx1 to Rx8) are provided in a display area DA. However, in the example of FIG. 18, each of the detection electrodes Rx1 to Rx8 has a shape which is long in the Y-direction, and the detection electrodes Rx1 to Rx8 are arranged in the X-direction. Thus, the extension direction (second direction) of the detection electrodes Rx1 to Rx8 is parallel to the extension direction of the signal lines SL shown in FIG. 1. The detection electrodes Rx1 to Rx8 are connected to the terminal portion T via leads Lb1 to Lb8.

In a manner similar to that of the example of FIG. 13, a plurality of floating electrodes FE are provided around the detection electrodes Rx1 to Rx8. The floating electrodes FE are arranged in the Y-direction (the extension direction of each detection electrode Rx) in areas between adjacent detection electrodes Rx and in areas located on the external sides of, among the detection electrodes Rx1 to Rx8, the detection electrodes Rx1 and Rx8 located at the both ends in the X-direction.

In the configuration of the example of FIG. 17 and FIG. 18, eight segments SG and eight detection electrodes Rx are provided. It should be noted that the number of segments SG or the number of detection electrodes Rx is not limited to this example. The number of segments SG may be different from the number of detection electrodes Rx.

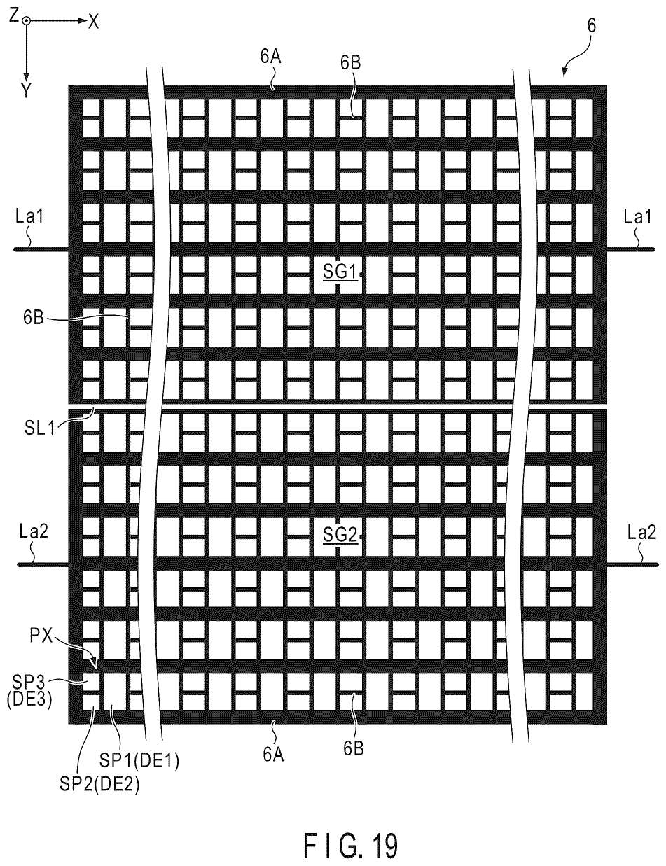

FIG. 19 is a schematic enlarged plan view showing an example of a configuration which could be applied to the segments SG according to this embodiment. This figure shows the vicinity of the boundary between the segments SG1 and SG2 and the leads La1 and La2. In a manner similar to that of the example of FIG. 14, the segments SG1 to SG8 comprise partitions 6A and 6B and are divided by slits SL1. In the example of FIG. 19, the partition 6A is provided between pixels PX arranged in the Y-direction. The partition 6B whose width is less than the partition 6A is provided between pixels PX arranged in the X-direction and between subpixels SP1, SP2 and SP3 in each pixel PX. In this configuration, compared to the example of FIG. 5, the number of partitions 6A extending in the Y-direction can be reduced, thereby increasing the width of each pixel PX in the X-direction. As a result, the aperture ratio of subpixels SP1, SP2 and SP3 constituting each pixel PX can be increased. Thus, the display quality can be improved. For example, as shown in the figure, the slit SL1 is provided in the partition 6A and extends in the X-direction.

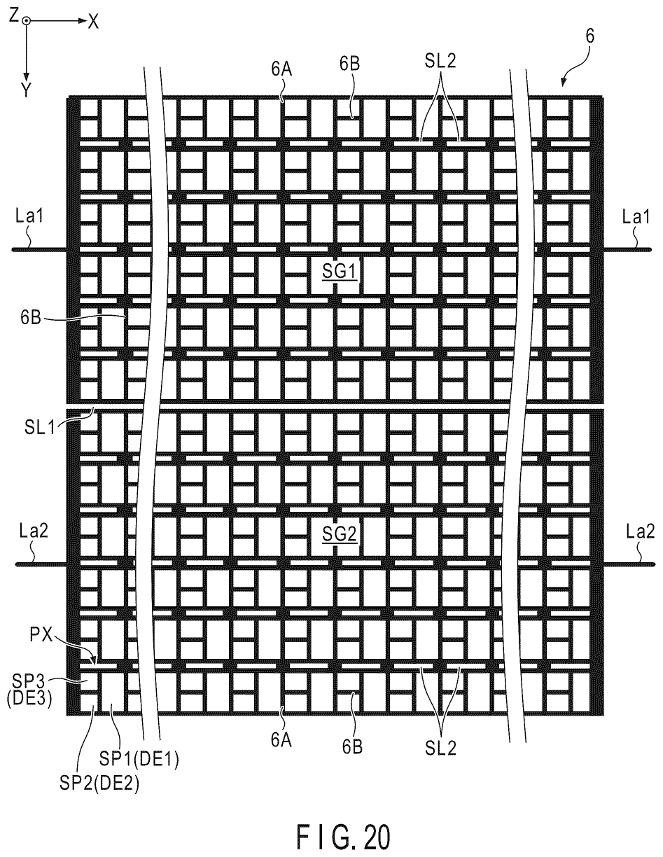

FIG. 20 is a schematic enlarged plan view showing another example of a configuration which could be applied to the segments SG according to this embodiment. In the example of this figure, in a manner similar to that of the example of FIG. 15, the partition 6A has a plurality of slits SL2 which are intermittently provided.

Each slit SL2 has, for example, a shape which is long in the X-direction. The slits SL2 are provided in portions extending in the X-direction in the partition 6A. As another example, the partition 6A may have a grating shape as shown in FIG. 7, and further, the slits SL2 may be provided in both portions extending in the X-direction and portions extending in the Y-direction in the partition 6A.

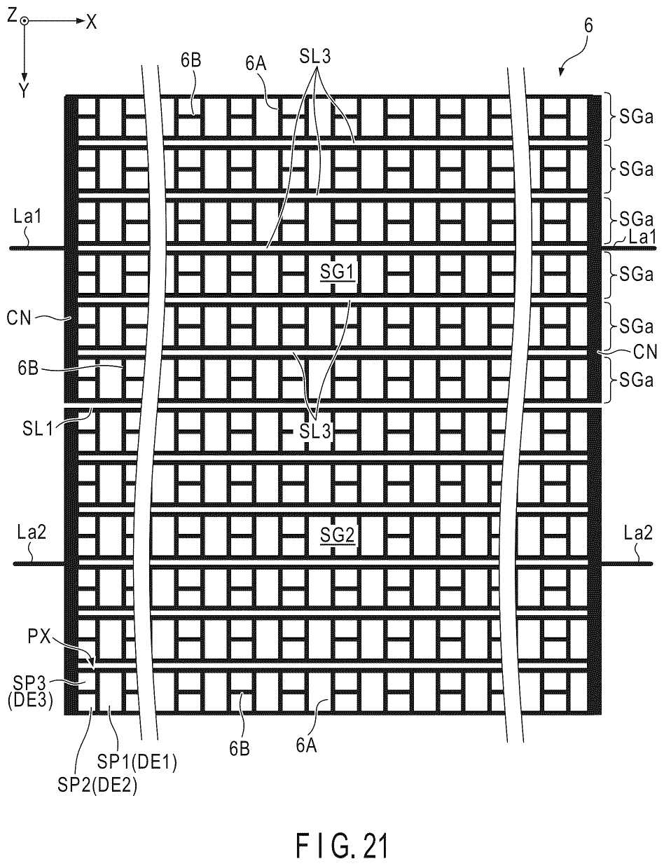

FIG. 21 is a schematic enlarged plan view showing yet another example of a configuration which could be applied to the segments SG according to this embodiment. In the example of this figure, in a manner similar to that of the example of FIG. 16, the segment SG1 has a plurality of sub-segments SGa into which the segment SG1 is divided by slits SL3. The sub-segments SGa are connected by a connection portion CN.

The slits SL3 extend in the X-direction in a manner similar to that of the slit SL1. In the example of FIG. 21, each list SL3 is provided between pixels PX which are adjacent to each other in the Y-direction. In other words, one pixel column arranged in the X-direction is provided between adjacent slits SL3. As another example, two or more pixel columns may be provided between adjacent slits SL3.

In the example of FIG. 21, regarding both ends of the sub-segments SGa in the X-direction, the ends are connected to each other by the connection portions CN. However, in a manner similar to that of the example of FIG. 16, ends of the sub-segments SGa may be connected to each other by the connection portion CN, and the other ends may not be connected to each other by the connection portion CN.

The configurations of the segments SG and the detection electrodes Rx disclosed in the third and fourth embodiments are merely examples. Various configurations can be applied to the segments SG and the detection electrodes Rx other than the configurations disclosed in the third and fourth embodiments.

All of the display devices that can be implemented by a person of ordinary skill in the art through arbitrary design changes to the display device described above as each embodiment of the present invention come within the scope of the present invention as long as they are in keeping with the spirit of the present invention.

Various modification examples which may be conceived by a person of ordinary skill in the art in the scope of the idea of the present invention will also fall within the scope of the invention. For example, even if a person of ordinary skill in the art arbitrarily modifies the above embodiments by adding or deleting a structural element or changing the design of a structural element, or by adding or omitting a step or changing the condition of a step, all of the modifications fall within the scope of the present invention as long as they are in keeping with the spirit of the invention.

Further, other effects which may be obtained from the above embodiments and are self-explanatory from the descriptions of the specification or can be arbitrarily conceived by a person of ordinary skill in the art are considered as the effects of the present invention as a matter of course.

What is claimed is:

1. A display device comprising:
a plurality of display elements each of which includes a lower electrode, an upper electrode facing the lower electrode, and an organic layer provided between the lower electrode and the upper electrode and emitting light based on a potential difference between the lower electrode and the upper electrode;
a rib which has a plurality of pixel apertures overlapping the display elements, respectively; and
a partition which includes a conductive lower portion provided on the rib and an upper portion protruding from a side surface of the lower portion and surrounds each of the display elements, wherein
the partition is divided into a plurality of segments for detecting an object which is in contact with or close to a display area including the display elements.

2. The display device of claim 1, further comprising:
a terminal portion provided in a surrounding area around the display area; and
a plurality of leads provided in the surrounding area and connecting the segments to the terminal portion.

3. The display device of claim 1, wherein
the partition includes:
a first partition having a grating shape; and
a second partition provided between a plurality of display elements included in a cell of the grating of the first partition, wherein
a width of the first partition is greater than a width of the second partition.

4. The display device of claim 3, wherein
the segments are divided by a first slit provided in the first partition.

5. The display device of claim 4, wherein
the first slit overlaps the rib.

6. The display device of claim 4, further comprising:
a first sealing layer which covers the display elements and the partition; and
a resin layer which covers the first sealing layer, wherein
the first slit is filled with the resin layer.

7. The display device of claim 4, wherein
the first partition has a plurality of second slits which are intermittently provided.

8. The display device of claim 7, wherein
a length of each of the second slits is less than or equal to a width of a cell of the grating of the first partition.

9. The display device of claim 1, wherein
the upper electrode is in contact with the lower portion.

10. The display device of claim 9, wherein
common voltage is applied to the upper electrode through the partition.

11. The display device of claim 10, further comprising a plurality of pixel circuits which drive the display elements, wherein
each of the pixel circuits includes a drive transistor having a p-type semiconductor layer, and
the lower electrode is connected to a drain electrode of the drive transistor.

12. The display device of claim 1, further comprising a plurality of detection electrodes which face the segments and output a signal based on capacitance between the detection electrodes and the segments.

13. The display device of claim 12, wherein
the segments extend in a first direction and are arranged in a second direction intersecting with the first direction, and
the detection electrodes extend in the second direction and are arranged in the first direction.

14. The display device of claim 13, further comprising:
a plurality of pixel circuits which drive the display elements, respectively;
a plurality of signal lines which supply a video signal to the pixel circuits; and
a plurality of scanning lines which supply a scanning signal to the pixel circuits, wherein
the first direction is parallel to an extension direction of the signal lines, and
the second direction is parallel to an extension direction of the scanning lines.

15. The display device of claim 13, further comprising:
a plurality of pixel circuits which drive the display elements, respectively;
a plurality of signal lines which supply a video signal to the pixel circuits; and
a plurality of scanning lines which supply a scanning signal to the pixel circuits, wherein
the first direction is parallel to an extension direction of the scanning lines, and
the second direction is parallel to an extension direction of the signal lines.

16. The display device of claim 12, further comprising:
a first substrate in which the partition is formed;
a second substrate in which the detection electrodes are formed; and
an adhesive layer which attaches the first substrate and the second substrate to each other.

17. The display device of claim 12, further comprising:
a first sealing layer which covers the display elements and the partition;
a resin layer which covers the first sealing layer; and
a second sealing layer which covers the resin layer, wherein
the detection electrodes are provided on the second sealing layer.

18. The display device of claim 12, further comprising a plurality of floating electrodes provided between adjacent two detection electrodes of the plurality of detection electrodes and spaced apart from the two detection electrodes.

19. The display device of claim 18, wherein
the floating electrodes are arranged in an extension direction of the detection electrodes.

20. The display device of claim 12, wherein
at least one of the segments includes:
a plurality of sub-segments into which the segment is divided by a third slit; and
a connection portion which connects the sub-segments to each other.
